(19) United States
(12) Patent Application Publication
(10) Pub. No.: US 2024/0421084 A1
(43) Pub. Date: Dec. 19, 2024

(54) SEMICONDUCTOR STORAGE DEVICE AND METHOD FOR MANUFACTURING SEMICONDUCTOR STORAGE DEVICE

(71) Applicant: Kioxia Corporation, Tokyo (JP)

(72) Inventor: Kyosuke NANAMI, Yokkaichi Mie (JP)

(21) Appl. No.: 18/743,037

(22) Filed: Jun. 13, 2024

(30) Foreign Application Priority Data
Jun. 14, 2023 (JP) 2023-097629

(51) Int. Cl. H01L 23/528; H01L 23/532; H10B 41/27; H10B 43/27

(52) U.S. Cl. CPC H01L 23/5283; H01L 23/53295; H10B 41/27; H10B 43/27

(57) ABSTRACT

A semiconductor storage device includes a stacked body having a plurality of conductive layers and a plurality of first insulating layers that are alternately stacked, and a staircase portion in which the plurality of conductive layers have been processed into a staircase shape, a contact disposed in the staircase portion and connected to a first conductive layer, which is one of the plurality of conductive layers, and a first pillar that extends in a stacking direction of the stacked body in a portion of the stacked body different from the staircase portion and forms memory cells at each intersection of the first pillar and at least a part of the plurality of conductive layers. The contact penetrates a second conductive layer, which is not one of the plurality of conductive layers and disposed above the first conductive layer, and reaches the first conductive layer to be in contact therewith.

### CROSS-REFERENCE TO RELATED APPLICATION(S)

This application is based upon and claims the benefit of priority from Japanese Patent Application No. 2023-097629, filed Jun. 14, 2023, the entire contents of which are incorporated herein by reference.

### FIELD

Embodiments described herein relate generally to a semiconductor storage device and a method for manufacturing a semiconductor storage device.

### BACKGROUND

In general, in a semiconductor storage device such as a three-dimensional non-volatile memory, a memory cell is formed three-dimensionally in a stacked body in which a plurality of conductive layers are stacked. In order to provide an electrical connection to the conductive layers, a plurality of contacts are disposed, each of which is connected to a portion of the plurality of conductive layers that are processed in a staircase shape. In addition, a plurality of dummy pillars for supporting the stacked body are disposed in the stacked body. When contact occurs between the contacts and the dummy pillars, a short circuit defect may occur in the contacts.

### DESCRIPTION OF THE DRAWINGS

FIG. 1 is a cross-sectional view illustrating an example of a schematic configuration of a semiconductor storage device according to an embodiment.

FIGS. 2A to 2C are cross-sectional views illustrating an example of a configuration of the semiconductor storage device according to the embodiment.

FIGS. 3A to 3D are views sequentially illustrating a part of the procedure of a method for manufacturing a semiconductor storage device according to the embodiment.

FIGS. 4A to 4C are views sequentially illustrating a part of the procedure of the method for manufacturing a semiconductor storage device according to the embodiment.

FIGS. 5A to 5C are views sequentially illustrating a part of the procedure of the method for manufacturing a semiconductor storage device according to the embodiment.

FIGS. 6A to 6C are views sequentially illustrating a part of the procedure of the method for manufacturing a semiconductor storage device according to the embodiment.

FIGS. 7A to 7C are views sequentially illustrating a part of the procedure of the method for manufacturing a semiconductor storage device according to the embodiment.

FIGS. 8A to 8C are views sequentially illustrating a part of the procedure of the method for manufacturing a semiconductor storage device according to the embodiment.

FIGS. 9A and 9B are views sequentially illustrating a part of the procedure of the method for manufacturing a semiconductor storage device according to the embodiment.

FIGS. 10A to 10D are views sequentially illustrating a part of the procedure of the method for manufacturing a semiconductor storage device according to the embodiment.

FIGS. 11A to 11C are views sequentially illustrating a part of the procedure of the method for manufacturing a semiconductor storage device according to the embodiment.

FIGS. 12A to 12F are enlarged cross-sectional views along an X direction illustrating the details of a contact formation process of the semiconductor storage device according to the embodiment.

FIGS. 13A to 13F are enlarged cross-sectional views along the X direction illustrating the details of the contact formation process of the semiconductor storage device according to the embodiment.

FIGS. 14A to 14F are enlarged cross-sectional views along the X direction illustrating the details of the contact formation process of the semiconductor storage device according to the embodiment.

FIGS. 15A to 15F are enlarged cross-sectional views along the X direction illustrating the contact formation process of the semiconductor storage device according to the comparative example.

### DETAILED DESCRIPTION

Embodiments provide a semiconductor storage device and a method for manufacturing a semiconductor storage device capable of preventing a short circuit problem with a contact even when the contact and a dummy pillar are in contact with each other.

In general, according to one embodiment, a semiconductor storage device includes a stacked body having a plurality of conductive layers and a plurality of first insulating layers that are alternately stacked, and a staircase portion in which the plurality of first conductive layers have been processed into a staircase shape, a contact disposed in the staircase portion and connected to a first conductive layer, which is one of the plurality of conductive layers, and a first pillar that extends in a stacking direction of the stacked body in a portion of the stacked body different from the staircase portion and forms memory cells at each intersection of the first pillar and at least a part of the plurality of conductive layers. The contact penetrates a second conductive layer, which is not one of the plurality of conductive layers and disposed above the first conductive layer, and reaches the first conductive layer to be in contact therewith.

Hereinafter, embodiments of the present disclosure will be described in detail with reference to the drawings. Further, the present disclosure is not limited to the following embodiment. The elements in the following embodiments include those that can be easily implemented by those skilled in the art or those that are substantially the same.

### Configuration Example of Semiconductor Storage Device

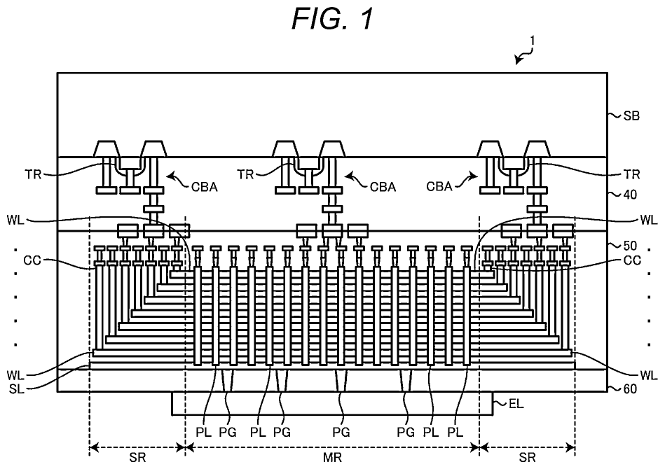

FIG. 1 is a cross-sectional view illustrating an example of a schematic configuration of a semiconductor storage device 1 according to an embodiment. However, in FIG. 1, hatching is omitted in consideration of the visibility of the drawing.

As illustrated in FIG. 1, the semiconductor storage device 1 includes a semiconductor substrate SB on which an electrode film EL, a source line SL, a plurality of word lines WL, and a peripheral circuit CBA are provided in order from the lower side of the drawing.

The source line SL is disposed on the electrode film EL with an insulating layer 60 interposed therebetween. A plurality of plugs PG are disposed in the insulating layer 60, and the source line SL and the electrode film EL are electrically conducted to each other through the plugs PG. Although not illustrated, an electrode pad for supplying power and a signal to the semiconductor storage device 1 from the outside is provided in the same layer as the electrode film EL. A plurality of word lines WL are stacked on the source line SL.

A memory region MR is disposed at a central portion of the plurality of word lines WL, and staircase regions SR are disposed at both end portions of the plurality of word lines WL, respectively.

A plurality of pillars PL penetrating the plurality of word lines WL in a stacking direction are disposed in the memory region MR. A lower end of the pillar PL reaches the source line SL. A plurality of memory cells are formed at intersections of the pillar PL and the word line WL. Thereby, the semiconductor storage device 1 is configured as, for example, a three-dimensional non-volatile memory in which the memory cells are disposed in three dimensions in the memory region MR.

In the staircase region SR, the plurality of word lines WL are processed into a staircase shape and terminate. At this time, as the plurality of word lines WL that form a terrace portion move from an upper layer side to a lower layer side as ends of the word lines WL move farther away from the memory region MR, the height position of the terrace portion moves toward the source line SL side.

A contact CC connected to the word line WL of each layer is disposed in the terrace portion of each step of the plurality of word lines WL. An electrical connection to the word lines WL and the like, which are stacked in multiple layers, is individually made through the contacts CC.

More specifically, through the contacts CC, a write voltage, a read voltage, and the like are applied to the memory cells provided in the memory region MR at the central portion of the plurality of word lines WL through the word lines WL at the same height position as the memory cells.

The plurality of word lines WL, the plurality of pillars PL, and the plurality of contacts CC are covered with the insulating layer 50. The insulating layer 50 also extends around the configurations.

The semiconductor substrate SB above the insulating layer 50 is, for example, a silicon substrate or the like. A peripheral circuit CBA including a transistor TR, a wiring, and the like is disposed on a surface of the semiconductor substrate SB. Various voltages applied through the contact CC to the memory cell are controlled by the peripheral circuit CBA electrically connected to the contacts CC. Thereby, the peripheral circuit CBA controls the electrical operation of the memory cell.

By bonding an insulating layer 40 covering the peripheral circuit CBA to the insulating layer 50 covering the plurality of word lines WL, and the like, the semiconductor storage device 1 has a configuration including the plurality of word lines WL, the plurality of pillars PL, and the plurality of contacts CC, and the peripheral circuit CBA.

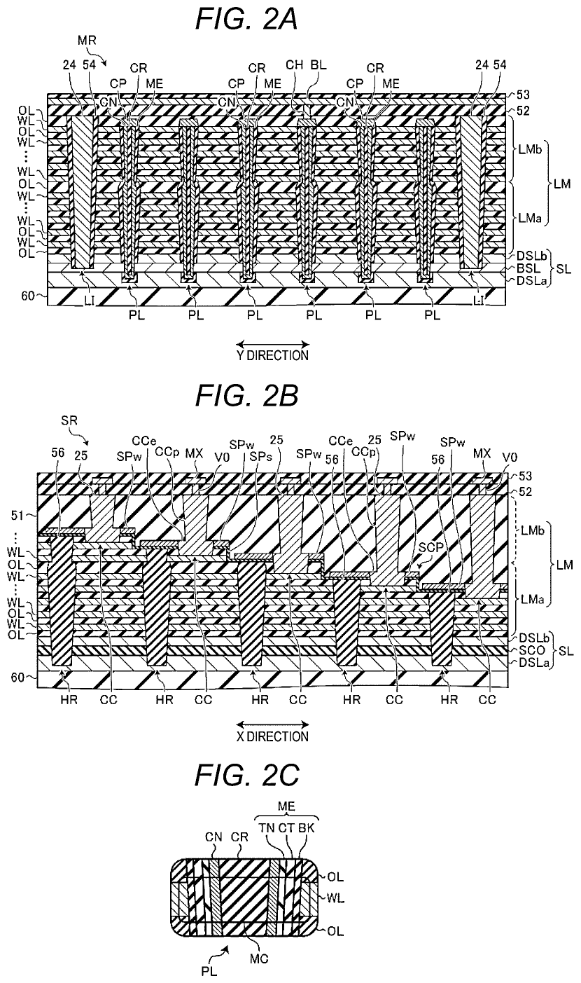

Next, a detailed configuration example of the semiconductor storage device 1 will be described with reference to FIGS. 2A to 2C. FIGS. 2A to 2C are cross-sectional views illustrating an example of a configuration of the semiconductor storage device 1 according to the embodiment.

More specifically, FIG. 2A is a cross-sectional view taken along the Y direction in the memory region MR of the semiconductor storage device 1. FIG. 2B is a cross-sectional view taken along the X direction in the staircase region SR of the semiconductor storage device 1. In FIGS. 2A and 2B, the structure below the insulating layer 60 and the structure above an insulating layer 53 to be described later are omitted.

FIG. 2C is an enlarged cross-sectional view of the pillar PL at a height position of any word line WL.

In the present specification, both the X direction and the Y direction are directions along a surface of the word line WL, and the X direction and the Y direction are orthogonal to each other. A direction of current flow through the word line WL may be referred to as a first direction, and the first direction is a direction along the X direction. A direction intersecting the first direction may be referred to as a second direction, and the second direction is a direction along the Y direction. However, since the semiconductor storage device 1 may include a manufacturing error, the first direction and the second direction are not necessarily orthogonal to each other.

In addition, in the present specification, a direction that a terrace surface of each step of the word line WL in the staircase region SR faces is defined as an upward direction in the semiconductor storage device 1.

As illustrated in FIG. 2A, the source line SL has a multilayer structure in which, for example, a lower source line DSLa, an intermediate source line BSL, and an upper source line DSLb are stacked in this order on the insulating layer 60. Moreover, the intermediate source line BSL is disposed below the memory region MR of the stacked body LM.

The lower source line DSLa, the intermediate source line BSL, and the upper source line DSLb are, for example, a polysilicon layer or the like. Among them, at least the intermediate source line BSL may be a conductive polysilicon layer or the like in which an impurity is diffused.

Further, the source line SL is connected to the peripheral circuit CBA via the electrode film EL by a through contact (not illustrated) extending from the electrode film EL to the peripheral circuit CBA through the above-described insulating layer 50 outside the stacked body LM.

The stacked body LM is disposed on the source line SL. The stacked body LM includes stacked bodies LMa and LMb in which a plurality of word lines WL and a plurality of insulating layers OL are alternately stacked one layer by one layer.

The stacked body LMa is disposed above the source line SL. One or more select gate lines may be disposed in a layer lower than the lowermost word line WL of the stacked body LMa. The stacked body LMb is disposed on the stacked body LMa. One or more select gate lines may be disposed in a layer higher than the uppermost word line WL of the stacked body LMb.

Furthermore, the number of layers of the word lines WL and the select gate lines in the stacked body LM is not limited to any particular number. The word lines WL and the select gate lines are, for example, a tungsten layer, a molybdenum layer, or the like. The insulating layer OL is, for example, a silicon oxide layer.

An upper surface of the stacked body LM is covered with an insulating layer 52. The insulating layer 52 is covered with an insulating layer 53. The insulating layers 52 and 53 are each a part of the insulating layer 50 in FIG. 1 together with the insulating layer 51 to be described below.

As described above, the stacked body LM is divided in the Y direction by a plurality of plate-shaped contacts LI. That is, each of the plate-shaped contacts LI is arranged in the Y direction, and extends in the stacking direction and the X direction.

The plate-shaped contact LI continuously extends from one end portion to the other end portion in the X direction of the stacked body LM within the stacked body LM. In addition, the plate-shaped contact LI penetrates the stacked body LM and the upper source line DSLb, and reaches the intermediate source line BSL in the memory region MR.

Each of the plate-shaped contacts LI includes an insulating layer 54 and a conductive layer 24. The insulating layer 54 is, for example, a silicon oxide layer. The conductive layer 24 is, for example, a tungsten layer or a conductive polysilicon layer.

The insulating layer 54 covers the side wall of the plate-shaped contact LI facing the Y direction. The conductive layer 24 is filled inside the insulating layer 54 and is electrically connected to the source line SL including the intermediate source line BSL. However, instead of the plate-shaped contact LI, a plate-shaped member which is filled with an insulating layer may penetrate the stacked body LM and extend in the direction along the X direction, so that the stacked body LM may be divided in the Y direction.

A plurality of pillars PL are disposed in a dispersed manner in the memory region MR, the pillars PL reaching the lower source line DSLa through the stacked body LM, the upper source line DSLb, and the intermediate source line BSL.

The pillars PL are arranged in a staggered shape, for example, when viewed in the stacking direction of the stacked body LM. Each of the pillars PL has a shape such as a circular shape, an elliptical shape, or an oval shape as a cross-sectional shape in a direction along the stacking direction of the stacked body LM, that is, in a direction along the XY plane.

In addition, the pillar PL has a tapered shape in which the XY cross-sectional area are reduced from the upper layer side toward the lower layer side in the portion that penetrates the stacked body LMa and the portion that penetrates the stacked body LMb, respectively. Alternatively, the pillar PL has, for example, a bow shape in which the XY cross-sectional area thereof is maximum at a predetermined position between the upper layer side and the lower layer side in the portion penetrating the stacked body LMa and the portion penetrating the stacked body LMb, respectively.

Each of the plurality of pillars PL has a memory layer ME that extends in the stacking direction within the stacked body LM, a channel layer CN that penetrates the stacked body LM and is connected to the intermediate source line BSL, a cap layer CP that covers the upper surface of the channel layer CN, and a core layer CR that is a core material of the pillar PL.

As illustrated in FIG. 2C, the memory layer ME has a multilayer structure in which a block insulating layer BK, a charge storage layer CT, and a tunnel insulating layer TN are stacked in this order from the outer peripheral side of the pillar PL. More specifically, the memory layer ME is disposed on a side surface of the pillar PL except at a depth position of the intermediate source line BSL. In addition, the memory layer ME is also disposed on a bottom surface of the pillar PL reaching the lower source line DSLa.

The channel layer CN is inside the memory layer ME, penetrates the stacked body LM, the upper source line DSLb, and the intermediate source line BSL, and reaches the lower source line DSLa. More specifically, the channel layer CN is disposed on the side surface and the bottom surface of the pillar PL and surrounded by the memory layer ME. A part of the channel layer CN is in contact with the intermediate source line BSL on the side surface thereof, and thus is electrically connected to the source line SL including the intermediate source line BSL. The core layer CR is filled on the inner side of the channel layer CN.

In addition, each of the plurality of pillars PL has a cap layer CP at an upper end portion. The cap layer CP is disposed on the upper end portion of the pillar PL at least to cover the upper end portion of the channel layer CN and is connected to the channel layer CN. In addition, the cap layer CP is connected to a bit line BL disposed in the insulating layer 53 via a plug CH disposed in the insulating layer 52. The bit line BL extends above the stacked body LM in the Y direction.

In FIG. 2A, the plug CH is connected to only one of the six pillars PL. The rest of pillars PL are each connected to one of other bit lines BL extending in the direction along the Y direction in parallel to the bit lines BL illustrated in FIG. 2A at a position different from the cross section illustrated in FIG. 2A via a respective plug CH (not illustrated in FIG. 2A).

The block insulating layer BK and the tunnel insulating layer TN of the memory layer ME, and the core layer CR are, for example, a silicon oxide layer. The charge storage layer CT of the memory layer ME is, for example, a silicon nitride layer. The channel layer CN and the cap layer CP are, for example, a semiconductor layer such as a polysilicon layer or an amorphous silicon layer.

As illustrated in FIG. 2C, the memory cell MC is formed in each portion of the pillar PL side surface facing the individual word lines WL to have the above-described configuration. Data is written to and read from the memory cell MC by applying a predetermined voltage to the word line WL.

In addition, when the stacked body LM has the select gate line above and below the word line WL, the select gates are respectively formed in the portions facing the select gate lines. By applying a predetermined voltage from each of the select gate lines, the select gate can be turned on or off, and the memory cell MC of the pillar PL to which the select gate belongs can be set to a selected state or an unselected state.

As illustrated in FIG. 2B, the staircase region SR has a staircase portion SCP in which a plurality of word lines WL are processed in a staircase shape. FIG. 2B illustrates a part of the plurality of word lines WL processed in a staircase shape.

A stopper layer SPs covering the staircase portion SCP along the staircase shape of the staircase portion SCP is disposed on the staircase portion SCP. In addition, a stopper layer SPw is disposed on the terrace surface of each step of the staircase portion SCP via the stopper layer SPs.

At this time, the stopper layer SPs is disposed on the step surface of each step of the staircase portion SCP, and the stopper layer SPw is not disposed on the step surface. Therefore, for example, the word line WL having an end portion processed in a staircase shape on the step surface and the stopper layer SPw on the terrace surface of the lower stage are prevented from being in contact with each other so as to be electrically shorted with each other.

The staircase portion SCP is further covered with the insulating layer 51 above the stopper layers SPs and SPw. The insulating layer 51 reaches, for example, a height position of the top layer of the stacked body LM, and the insulating layers 52 and 53 also cover the upper surface of the insulating layer 51. As described above, the insulating layer 51 is a part of the insulating layer 50 in FIG. 1.

Here, the stopper layer SPs and the insulating layer 51 are, for example, a silicon oxide layer. In addition, the stopper layer SPw is, for example, a tungsten layer, a molybdenum layer, or the like, as in the word line WL described above.

In addition, in the staircase region SR, the source line SL includes an intermediate insulating layer SCO interposed between the upper source line DSLb and the lower source line DSLa instead of the intermediate source line BSL. The intermediate insulating layer SCO is, for example, a silicon oxide layer.

Therefore, the plate-shaped contact LI reaches the intermediate insulating layer SCO by penetrating the insulating layer 51, the stacked body LM, and the upper source line DSLb in the staircase region SR.

In addition, the plurality of contacts CC and a plurality of columnar portions HR are disposed in the staircase region SR. As will be described later, the columnar portions HR provide structural support when the stacked body LM is formed from a stacked body in which a sacrificial layer and an insulating layer are stacked, and do not contribute to the function of the semiconductor storage device 1.

Each of the individual contacts CC is connected to the word line WL immediately below the insulating layer OL, which forms the terrace surface of each step of the staircase portion SCP, by penetrating the insulating layer 51 and the stopper layers SPw and SPs.

In addition, each of the contacts CC includes an extension portion CCp extending in the insulating layer 51 and a lower end portion CCe including the portions that penetrate the stopper layers SPw and SPs. The outer shape of the lower end portion CCe is larger than the outer shape of the extension portion CCp. That is, the contact CC is enlarged in diameter at the lower end portion CCe. The contact CC has a conductive layer 25 such as a tungsten layer or a copper layer, and the conductive layer 25 continuously extends from the extension portion CCp to the lower end portion CCe.

The stopper layer SPw through which the contact CC penetrates is electrically connected to the word line WL that is connected to the contact CC via the lower end portion CCe of the contact CC. However, as described above, the stopper layer SPw is not in contact with any word line WL other than the word line WL connected to the contact CC, such as the word line WL having the end portion on the upper step surface of the terrace surface on which the stopper layer SPw is disposed. Therefore, for example, there is no problem in electrical characteristics such as a short circuit between the plurality of word lines WL through the stopper layer SPw.

The conductive layer 25 of each contact CC is connected to an upper layer wiring MX disposed in the insulating layer 53 via a plug VO disposed in the insulating layer 52. The upper layer wiring MX is electrically connected to the peripheral circuit CBA (refer to FIG. 1) described above.

With such a configuration, electrical connection to the word line WL of each layer can be provided from both end portions of the stacked body LM in the X direction. That is, with the above configuration, the peripheral circuit CBA can apply a predetermined voltage to the memory cell MC via the upper layer wiring MX, the contact CC, the word line WL, and the like, and can operate the memory cell MC as a storage element.

The columnar portion HR reaches the lower source line DSLa by penetrating the stacked bodies LMb and LMa processed in a staircase shape, the upper source line DSLb, and the intermediate insulating layer SCO.

More specifically, each of the columnar portions HR extends in the stacked body LM from the individual terrace surface of the staircase portion SCP of the word line WL and the insulating layer OL that is lower than the terrace surface. Therefore, the dimension of the columnar portion HR in an extending direction from the portion of the upper layer side word line WL processed in a staircase shape toward the portion of the lower layer side word line WL processed in a staircase shape, is shortened.

The columnar portions HR are distributed over the entire staircase portion SCP and are arranged in a grid pattern or in a staggered manner when viewed in the stacking direction of the stacked body LM. Each of the columnar portions HR has a shape such as a circular shape, an elliptical shape, or an oval shape as a cross-sectional shape in a direction along the XY plane.

In addition, when the columnar portion HR that penetrates the word line WL on the relatively upper layer side is taken as an example, the columnar portion HR has a tapered shape in which the diameter and the cross-sectional area are reduced from the upper layer side toward the lower layer side in a portion that penetrates the stacked body LMa and a portion that penetrates the stacked body LMb, respectively. Alternatively, the columnar portion HR has, for example, a bow shape in which the XY cross-sectional area thereof is maximum at a predetermined position between the upper layer side and the lower layer side in the portion penetrating the stacked body LMa and the portion penetrating the stacked body LMb, respectively.

The columnar portion HR is made entirely of an insulating layer 56 such as a silicon oxide layer. That is, the columnar portion HR includes the insulating layer 56 made with substantially a single material. Here, the substantially single material may include a case where the element ratio of the elements of the columnar portions HR is different in one columnar portion HR or between the plurality of columnar portions HR, and a case where the type and the amount of the impurities contained therein are different, and may also include a case where a void is allowed to be provided in the columnar portion HR of the single material.

Since the columnar portion HR is a single layer of the insulating layer 56 as described above, the columnar portion HR may not have an electrical influence on other configurations, and interference with the adjacent plate-shaped contact LI and the contact CC is allowed.

At the same height position of the stacked body LM, the XY cross-sectional area of the columnar portion HR is larger than, for example, the XY cross-sectional area of the pillar PL. In addition, the pitch between the plurality of columnar portions HR is larger than, for example, the pitch between the plurality of pillars PL, and the density of the columnar portions HR arranged per unit area of the word line WL in the stacked body LM is lower than the density of the pillars PL arranged per unit area of the word line WL.

In this way, for example, by configuring the cross-sectional area of the pillar PL to be smaller than that of the columnar portion HR and by making the pitch narrower, a large number of memory cells MC can be formed at a high density in the stacked body LM of a predetermined size, and the storage capacity of the semiconductor storage device 1 can be increased. On the other hand, since the columnar portion HR is used exclusively for supporting the stacked body LM, the manufacturing load can be reduced by not forming the columnar portion HR with a small cross-sectional area and a narrow pitch in a precise configuration like the pillar PL, for example.

### Method for Manufacturing Semiconductor Storage Device

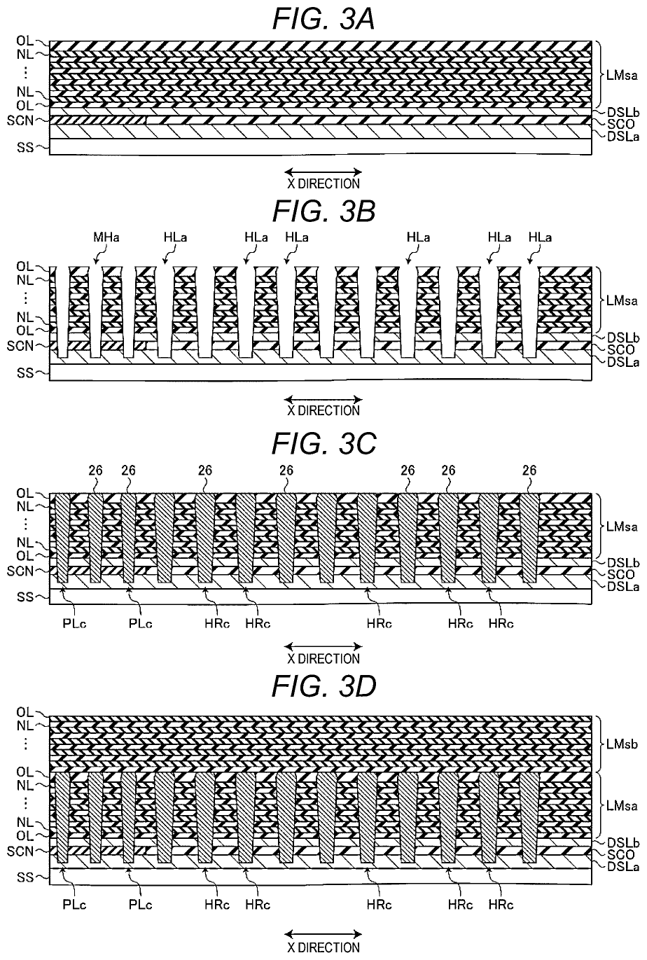

Next, a method for manufacturing the semiconductor storage device 1 according to the embodiment will be described with reference to FIGS. 3A to 14F. FIGS. 3A to 11C are views sequentially illustrating a part of the procedure of the method for manufacturing the semiconductor storage device 1 according to the embodiment.

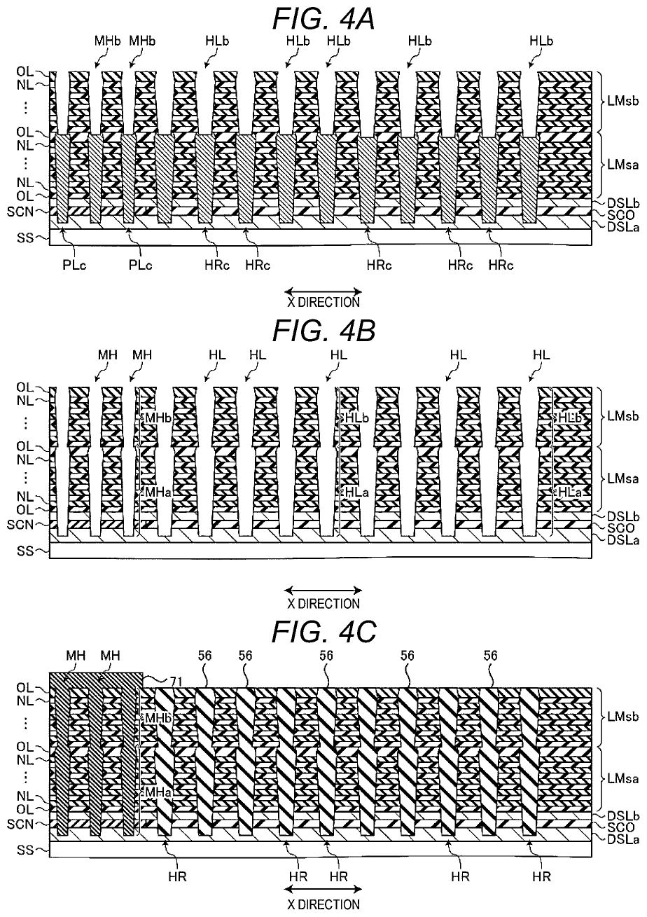

First, FIGS. 3A and 4C illustrate a state in which stacked bodies LMsa and LMsb each of which represents the stacked body LM before the word lines WL are formed and various configurations are formed in the stacked bodies LMsa and LMsb. FIGS. 3A and 4C are cross-sectional views taken along the X direction of a region that is to be the memory region MR and the staircase region SR later.

As illustrated in FIG. 3A, the lower source line DSLa, an intermediate sacrificial layer SCN or the intermediate insulating layer SCO, and the upper source line DSLb are formed in this order on a supporting substrate SS.

As the supporting substrate SS, a semiconductor substrate such as a silicon substrate, an insulating substrate such as a ceramic substrate, or a conductive substrate may be used, for example. The insulating layer 60 (refer to FIGS. 2A to 2C and the like) described above may be formed on the upper surface side of the supporting substrate SS.

The intermediate sacrificial layer SCN is formed in a region on the supporting substrate SS that is to be the memory region MR later, and the intermediate insulating layer SCO is formed in a region on the supporting substrate SS that is to be the staircase region SR later. The intermediate sacrificial layer SCN is, for example, a silicon nitride layer or the like, and is a layer that is later replaced with a polysilicon layer or the like to become the intermediate source line BSL. The intermediate insulating layer SCO is, as described above, for example, a silicon oxide layer.

In addition, the stacked body LMsa in which insulating layers NL and the insulating layers OL are alternately stacked in one layer each is formed on the upper source line DSLb. The insulating layer NL is, for example, a silicon nitride layer or the like, and functions as a sacrificial layer to be replaced with a conductive material to become the word line WL later.

As illustrated in FIG. 3B, for example, a plurality of memory holes MHa and a plurality of holes HLa extending in the stacking direction are collectively formed in the stacked body LMsa. The memory hole MHa is a portion that is to be a lower structure of the pillar PL later. The hole HLa is a portion that is to be a lower structure of the columnar portion HR later.

As illustrated in FIG. 3C, the memory holes MHa and the holes HLa are filled with a sacrificial layer 26 such as an amorphous silicon layer or a CVD-carbon layer.

Thereby, a pillar PLc in which the plurality of memory holes MHa are filled with the sacrificial layer 26 is formed in the region that is to be the memory region MR later. In addition, a columnar portion HRc in which the plurality of holes HLa are filled with the sacrificial layer 26 is formed in a region that is to be the staircase region SR later.

As illustrated in FIG. 3D, the stacked body LMsb is formed by alternately stacking the insulating layer NL and the insulating layer OL in one layer by one layer to cover the stacked body LMsa. The insulating layer NL of the stacked body LMsb is replaced with a conductive layer that later becomes the word line WL.

As illustrated in FIG. 4A, for example, a plurality of memory holes MHb and a plurality of holes HLb extending in the stacking direction are collectively formed in the stacked body LMsb. The memory hole MHb is a portion that is to be an upper structure of the pillar PL later. The hole HLb is a portion that is to be an upper structure of the columnar portion HR later.

The plurality of memory holes MHb are disposed in a region that is to be the memory region MR later, and respectively reach the upper end portions of the pillars PLc formed in the stacked body LMsa, penetrating the stacked body LMsb.

The plurality of holes HLb are disposed in a region that is to be a staircase region SR later, and respectively reach the upper end portion of the columnar portion HRc formed in the stacked body LMsa by penetrating the stacked body LMsb.

As illustrated in FIG. 4B, the sacrificial layer 26 is removed from the memory hole MHb, the pillar PLc, and the columnar portion HRc at the bottom of the hole HLb.

As a result, a plurality of memory holes MH are formed, each having the memory hole MHa open at the bottom of the plurality of memory holes MHb, penetrating the stacked bodies LMsb and LMsa, the upper source line DSLb, and the intermediate sacrificial layer SCN, and reaching the lower source line DSLa. In addition, a plurality of holes HL are formed, each having the hole HLa open at the bottom of the plurality of holes HLb, penetrating the insulating layer 51, the stacked bodies LMsb and LMsa, the upper source line DSLb, and the intermediate insulating layer SCO, and reaching the lower source line DSLa.

When the sacrificial layer 26 filling the pillar PLc and the columnar portion HRc is a CVD-carbon layer or the like, the sacrificial layer 26 can be collectively removed from the pillar PLc and the columnar portion HRc when the mask pattern and the like used in the processing of FIG. 4A described above are removed by ashing using oxygen plasma or the like.

As illustrated in FIG. 4C, the plurality of memory holes MH are covered with a mask layer such as a photoresist layer, and the hole HL is filled with the insulating layer 56 such as a silicon oxide layer. Thereby, the columnar portion HR penetrating the stacked bodies LMsa and LMsb is formed.

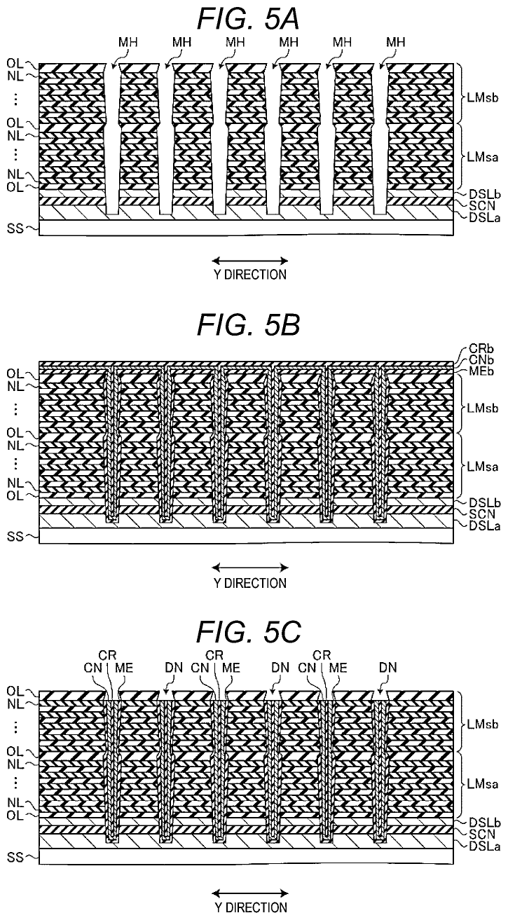

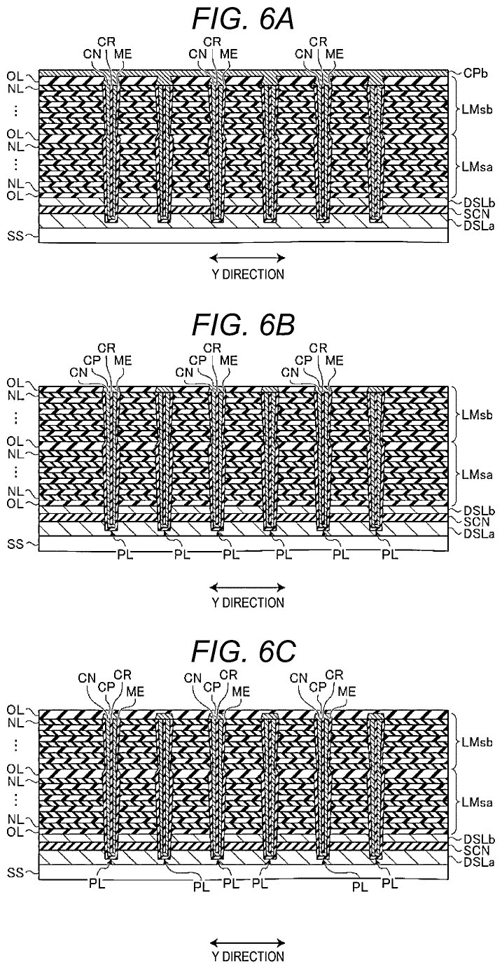

Next, a state in which the pillar PL is formed will be described with reference to FIGS. 5A to 6C.

FIGS. 5A to 6C are cross-sectional views taken along the Y direction of a region that is to be the memory region MR later, and show a cross section corresponding to the cross section of FIG. 2A described above.

As illustrated in FIG. 5A, a plurality of memory holes MH penetrating the stacked bodies LMsa and LMsb are formed in a region that is to be the memory region MR later.

As illustrated in FIG. 5B, a multilayer insulating layer MEb, a semiconductor layer CNb, and an insulating layer CRb are formed in this order in the memory hole MH. Thereby, the multilayer insulating layer MEb and the semiconductor layer CNb are disposed on a side surface of the memory hole MH and on the bottom surface on which the lower source line DSLa is exposed, and the center portion of the memory hole MH is filled with the insulating layer CRb.

The multilayer insulating layer MEb is an insulating layer having a multilayer structure that is to be the memory layer ME later. The semiconductor layer CNb is a layer that is to be the channel layer CN later. The insulating layer CRb is a silicon oxide layer or the like that is to be the core layer CR later.

The multilayer insulating layer MEb, the semiconductor layer CNb, and the insulating layer CRb are also formed in this order on the upper surface of the stacked body LMsb.

As illustrated in FIG. 5C, the insulating layer CRb, the semiconductor layer CNb, and the multilayer insulating layer MEb are subsequently etched in this order to be removed from the upper surface of the stacked body LMsb, and a depression DN is formed at the upper end portion of the memory hole MH.

Thereby, the memory layer ME, the channel layer CN, and the core layer CR are sequentially formed in the memory hole MH from the outer peripheral side.

As illustrated in FIG. 6A, a semiconductor layer CPb is formed in the depression DN at the upper end portion of the memory hole MH. The semiconductor layer CPb is a layer that is to be the cap layer CP later. The semiconductor layer CPb is also formed on the upper surface of the stacked body LMsb.

As illustrated in FIG. 6B, the semiconductor layer CPb on the upper surface of the stacked body LMsb is removed by CMP or the like, and the cap layer CP is formed at the upper end portion of the memory hole MH.

As illustrated in FIG. 6C, the top insulating layer OL of the stacked body LMsb thinned by CMP or the like is stacked. Thereby, the pillar PL in which the cap layer CP is buried in the top insulating layer OL is formed.

At this time, the memory layer ME covers the entire side wall of the pillar PL, and a part of the side surface of the channel layer CN is not exposed from the memory layer ME.

The region that is to be the staircase region SR later is previously formed with the plurality of columnar portions HR, and is hardly affected by the processing of FIGS. 5A and 6C described above. However, by the processing of FIGS. 6B and 6C, the upper end portion of the columnar portion HR is also buried in the top insulating layer OL.

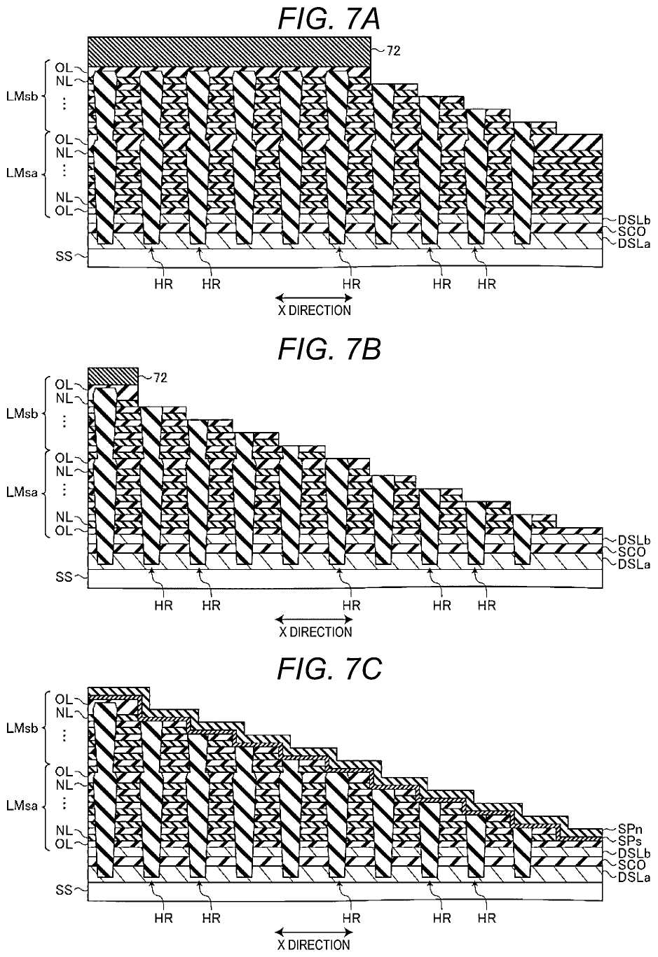

Next, a state in which a staircase structure and the contact CC are formed in a region that is to be the staircase region SR later will be described with reference to FIGS. 7A to 9B. FIGS. 7A to 9B are cross-sectional views taken along the X direction of a region that is to be a staircase region SR later.

As illustrated in FIG. 7A, the insulating layer NL and the insulating layer OL are processed in a staircase shape in a region that is to be the staircase region SR later. Such processing may be performed by repeating a plurality of times slimming of a mask pattern 72 such as a photoresist layer and etching of the insulating layer NL and the insulating layer OL subsequently exposed from the mask pattern 72.

That is, a mask pattern is formed on the upper surface of the stacked body LMsb, and, for example, the insulating layer NL and the insulating layer OL of the exposed portion are etched and removed in one layer each. In addition, the end portion of the mask pattern is retreated by processing with oxygen plasma or the like to newly expose the upper surface of the stacked body LMsb, and the insulating layer NL and the insulating layer OL are further etched and removed in one layer each. By repeating such processing a plurality of times, first, the stacked body LMsb is formed with the above-described staircase shape.

As illustrated in FIG. 7B, the repeated process of slimming the mask pattern 72 and etching the insulating layer NL and the insulating layer OL is continued for the stacked body LMsa. Thereby, the stacked body LMsa also has a staircase shape.

In the processing of FIGS. 7A and 7B, the columnar portion HR that penetrates the stacked bodies LMsa and LMsb is also etched and removed in parallel with the processing of the layers of the stacked bodies LMsa and LMsb. Thereby, the plurality of columnar portions HR extending through the insulating layer NL and the insulating layer OL of the lower layer of the terrace surfaces are formed from each of the terrace surfaces of the stacked bodies LMsa and LMsb having the staircase shape.

As illustrated in FIG. 7C, the stopper layers SPs and SPn are formed in this order along the staircase shape of the stacked bodies LMsa and LMsb. The stopper layer SPs is, for example, a silicon oxide layer as described above. The stopper layer SPn is, for example, a silicon nitride layer or the like, and is a layer that is later replaced with a tungsten layer or the like to become the above-described stopper layer SPw.

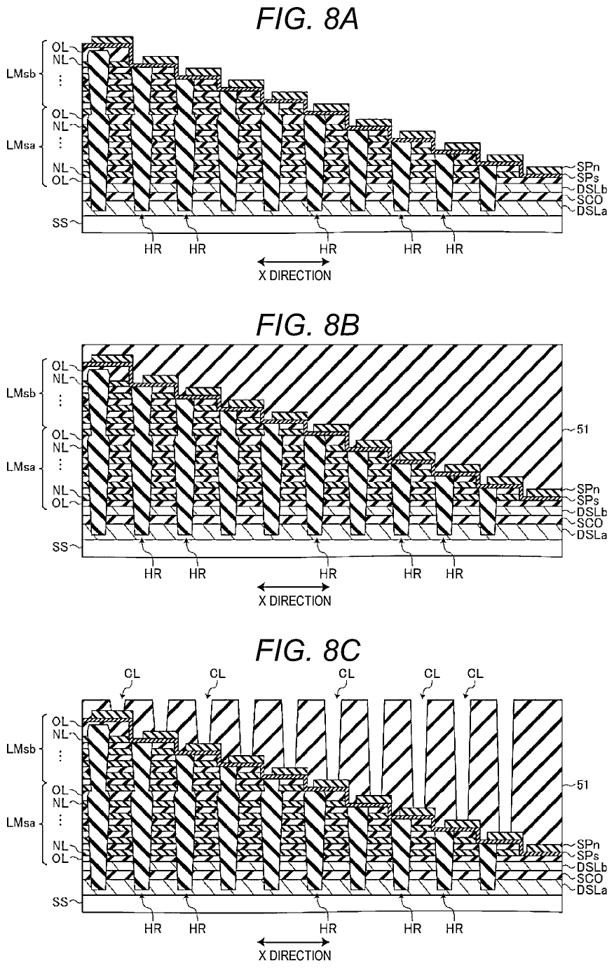

As illustrated in FIG. 8A, among the stopper layers SPn covering the staircase shapes of the stacked bodies LMsa and LMsb, the stopper layer SPn on the terrace surface is left intact while removing the stopper layer SPn on the step surface. Such processing may be performed by processing using anisotropic etching such as reactive ion etching (RIE).

As described above, by interposing the stopper layer SPs, which is a silicon oxide layer or the like, to form the stopper layer SPn, which is a silicon nitride layer or the like, and further by removing the stopper layer SPn from the step surface having a staircase shape, the stopper layer SPn on the predetermined terrace surface is provided in the step one above the terrace surface and is prevented from coming into contact with the insulating layer NL, which is also a silicon nitride layer or the like.

As illustrated in FIG. 8B, via the stopper layers SPs and SPn, the insulating layer 51, such as a silicon oxide layer, is formed to cover the staircase shapes of the stacked bodies LMsa and LMsb up to the height position of the unprocessed portions of the stacked bodies LMsa and LMsb.

As illustrated in FIG. 8C, a plurality of contact holes CL that penetrate through the insulating layer 51 and reach the stopper layer SPn covering the terrace surface of each step is formed. Such processing may be performed, for example, by etching the insulating layer 51 using highly selective conditions between the insulating layer 51 including different materials and the stopper layer SPn.

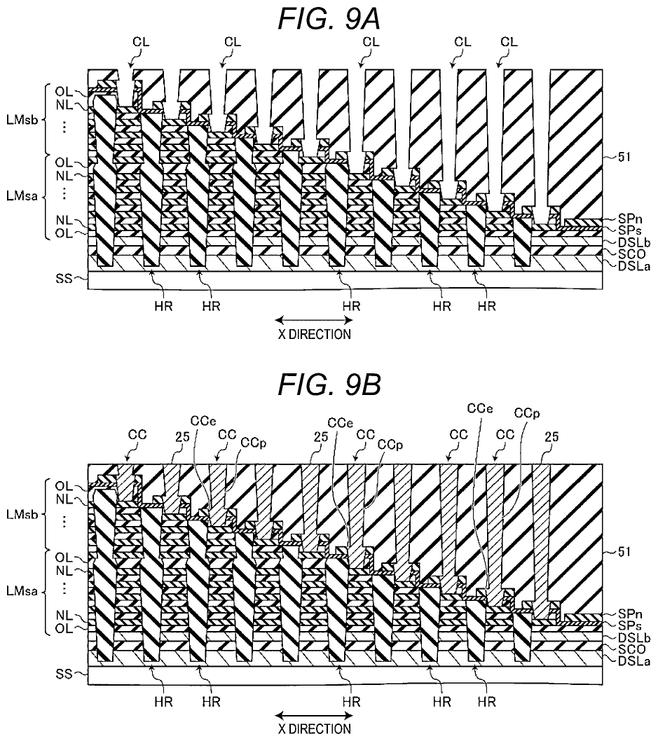

As illustrated in FIG. 9A, the stopper layers SPn and SPs and the insulating layer OL exposed on the bottom surfaces of the individual contact holes CL are subsequently removed, for example, by using wet etching or the like. More specifically, the bottom surface of the contact hole CL is processed by using a removal liquid for the stopper layer SPn, which is a silicon nitride layer or the like, and then the bottom surface of the contact hole CL is processed by using a removal liquid for the stopper layer SPs and the insulating layer OL, which are silicon oxide layers or the like.

As a result, a plurality of contact holes CL that respectively reach the insulating layer NL located immediately below the terrace surface of each step are obtained. At this time, for example, by using wet etching as described above, the contact hole CL having a shape in which the outer shape of the lower end portion including the portion that penetrates the stopper layers SPn and SPs and the insulating layer OL is larger than the outer shape of the other portions is obtained.

In addition, as described above, the stopper layer SPn is formed with the stopper layer SPs interposed therebetween, and the stopper layer SPn is further removed from the step surface having a staircase shape. Therefore, during the wet etching process, the insulating layer NL having the end portion on the step surface of each step is prevented from being removed.

As illustrated in FIG. 9B, the conductive layer 25 such as a tungsten layer is filled in each of the contact holes CL. As a result, a plurality of contacts CC are obtained, each of which includes the extension portion CCp extending in the insulating layer 51 and the lower end portion CCe having a diameter larger than that of the extension portion CCp.

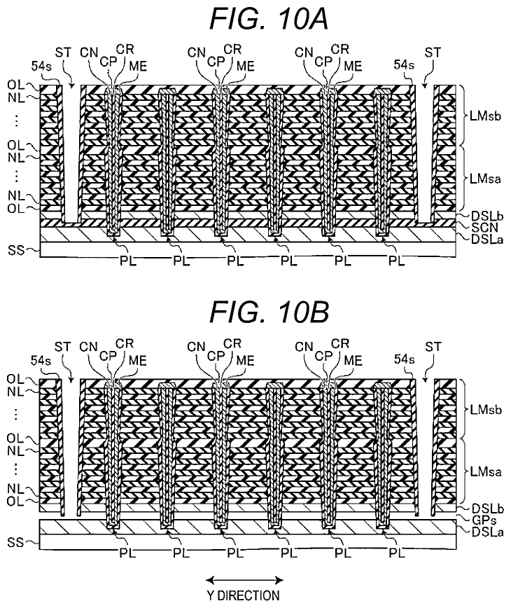

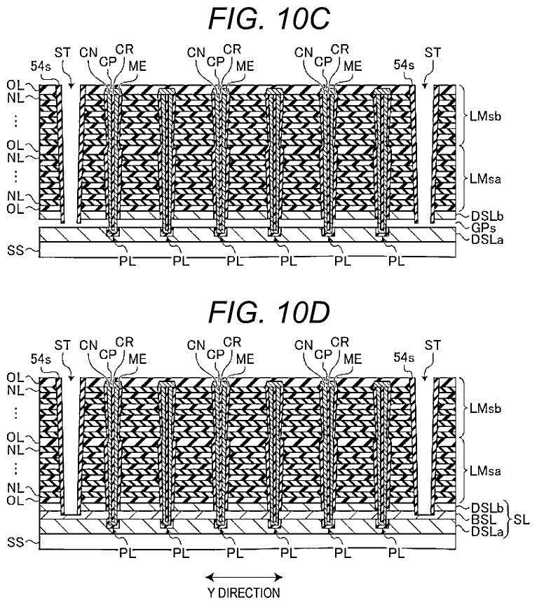

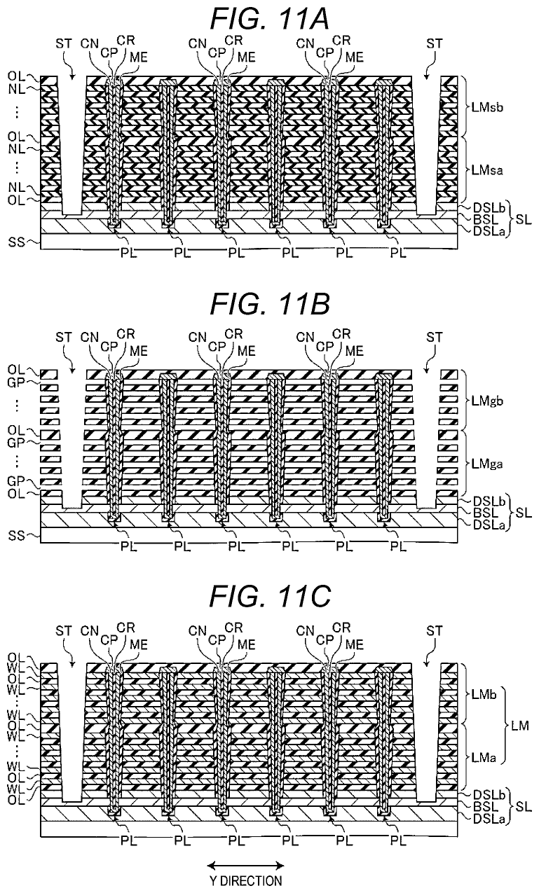

Next, a state in which the source line SL and the word line WL are formed will be described with reference to FIGS. 10A to 11C. FIGS. 10A to 11C are cross-sectional views taken along the Y direction of the region that is to be the memory region MR later, as in FIGS. 5A to 6C described above.

As illustrated in FIG. 10A, a slit ST that penetrates the stacked bodies LMsb and LMsa and the upper source line DSLb and reaches the intermediate sacrificial layer SCN is formed. In addition, an insulating layer 54s is formed on the side wall facing the slit ST in the Y direction.

The slit ST also extends in the direction along the X direction in the stacked bodies LMsa and LMsb. Therefore, in a region (not illustrated) that is to be the staircase region SR later, the lower end portion of the slit ST reaches the intermediate insulating layer SCO.

As illustrated in FIG. 10B, for example, a removal liquid for the intermediate sacrificial layer SCN such as hot phosphoric acid is allowed to flow into the slit ST whose side wall is protected by the insulating layer 54s to remove the intermediate sacrificial layer SCN interposed between the lower source line DSLa and the upper source line DSLb.

Thereby, a gap layer GPs is formed between the lower source line DSLa and the upper source line DSLb. In addition, a part of the memory layer ME of the outer peripheral portion of the pillar PL is exposed in the gap layer GPs.

At this time, since the side wall of the slit ST is protected by the insulating layer 54s, the insulating layer NL in the stacked bodies LMsa and LMsb is prevented from being removed. In addition, in the region that is to be the staircase region SR later, the intermediate sacrificial layer SCN is not provided between the lower source line DSLa and the upper source line DSLb, and the gap layer GPs is not formed.

As illustrated in FIG. 10C, a chemical solution is allowed to flow into the gap layer GPs through the slit ST as appropriate, and the block insulating layer BK, the charge storage layer CT, and the tunnel insulating layer TN (refer to FIG. 2C) of the memory layer ME exposed in the gap layer GPs are subsequently removed. Thereby, the memory layer ME is removed from a part of the side wall of the pillar PL, and a part of the inner channel layer CN is exposed in the gap layer GPs.

As illustrated in FIG. 10D, the gap layer GPs is filled with amorphous silicon or the like by injecting a raw material gas such as amorphous silicon from the slit ST whose side wall is protected by the insulating layer 54s. In addition, the supporting substrate SS is heat-treated to polycrystallize the amorphous silicon filling the gap layer GPs to form an intermediate source line BSL containing polysilicon or the like.

Thereby, a part of the channel layer CN of the pillar PL is connected to the source line SL on the side surface through the intermediate source line BSL.

At this time, in the region that is to be the staircase region SR later, the gap layer GPs is not formed between the lower source line DSLa and the upper source line DSLb. Therefore, the intermediate source line BSL is not formed.

As illustrated in FIG. 11A, the insulating layer 54s on the side wall of the slit ST is once removed.

As illustrated in FIG. 11B, the insulating layer NL of the stacked bodies LMsa and LMsb is removed by allowing, for example, a removal liquid for the insulating layer NL such as hot phosphoric acid to flow from the slit ST to the inside of the stacked bodies LMsa and LMsb. Thereby, stacked bodies LMga and LMgb having a plurality of gap layers GP from which the insulating layers NL between the insulating layers OL are removed are formed.

The stacked bodies LMga and LMgb including the plurality of gap layers GP have a fragile structure. In a region that is to be the memory region MR later, the plurality of pillars PL support such fragile stacked bodies LMga and LMgb. On the other hand, in the region that is to be the staircase region SR later, the plurality of columnar portions HR support the stacked bodies LMga and LMgb.

With the support structure of the pillar PL and the columnar portion HR, the remaining insulating layer OL is prevented from being bent, and the stacked bodies LMga and LMgb are prevented from being distorted or collapsed.

The slit ST penetrates the stopper layer SPn formed on the terrace surface of each step of the staircase shape in the region that is to be the staircase region SR later. Therefore, by the above processing, the stopper layer SPn, which is, for example, a silicon nitride layer, is also removed, and the gap layer is formed in the portion.

As illustrated in FIG. 11C, a raw material gas of a conductive material such as tungsten or molybdenum is injected from the slit ST into the stacked bodies LMga and LMgb, and the gap layers GP of the stacked bodies LMga and LMgb are filled with the conductive material to form a plurality of word lines WL and the like. Thereby, the stacked body LM as a second stacked body including stacked bodies LMa and LMb in which the plurality of word lines WL and the plurality of insulating layers OL are alternately stacked in one layer each is formed.

As described above, the process of forming the intermediate source line BSL from the intermediate sacrificial layer SCN and the process of forming the word line WL from the insulating layer NL are also referred to as replacement processes.

In a region that is to be the staircase region SR later, the gap layer generated by removing the stopper layer SPn is also filled with the conductive material through the slit ST. Thereby, the stopper layer SPw described above is formed.

At this time, as described above, since the contact between the stopper layer SPn and the insulating layer NL of each step is prevented, the stopper layer SPw after replacement is prevented from being conductive with the word line WL. In addition, since at least the contact hole CL is formed before the stopper layer SPn is replaced as described above, the formation process of the contact CC is easier than, for example, forming the contact CC by penetrating the hard stopper layer SPw.

Thereafter, the insulating layer 54 is formed on the side wall of the slit ST, and the insulating layer 54 is filled with the conductive layer 24 to form the plate-shaped contact LI. However, the slit ST may be filled with the insulating layer 54 and the like without forming the conductive layer 24, and a plate-shaped member may be formed in that manner.

In addition, the insulating layer 52 is formed on the upper surface of the insulating layer 51 covering the upper surface of the stacked body LM and the staircase region SR, and the plug VO connected to the contact CC is formed by penetrating the insulating layer 52. In addition, the plug CH connected to the pillar PL is formed by penetrating the insulating layer 52. Further, the insulating layer 53 is formed on the insulating layer 52 to form the upper layer wiring MX, the bit line BL, and the like connected to the plug VO and the plug CH. In addition, an electrode pad or the like that is electrically connected to the peripheral circuit CBA is formed on the upper surface of the insulating layer 53.

For example, the plugs VO and CH, the upper layer wiring MX, the bit line BL, and the like may be collectively formed by using a dual damascene method or the like.

In addition, the peripheral circuit CBA is formed on a semiconductor substrate SB separate from the supporting substrate SS on which the stacked body LM is formed, and is covered with the insulating layer 40. A contact, a via, a wiring, and the like for providing an electrical connection from the peripheral circuit CBA to the surface of the insulating layer 40 are formed in the insulating layer 40 and are connected to the electrode pad and the like formed on the upper surface of the insulating layer 40.

Subsequently, the supporting substrate SS and the semiconductor substrate SB are bonded to each other by the insulating layers 50 and 40 provided in each of the supporting substrate SS and the semiconductor substrate SB, and the electrode pads in the insulating layers 50 and 40 are connected to each other. Thereafter, the supporting substrate SS is removed to expose the source line SL, and the electrode film EL is connected via the insulating layer 60 in which the plug PG is formed.

As described above, the semiconductor storage device 1 of the embodiment is manufactured.

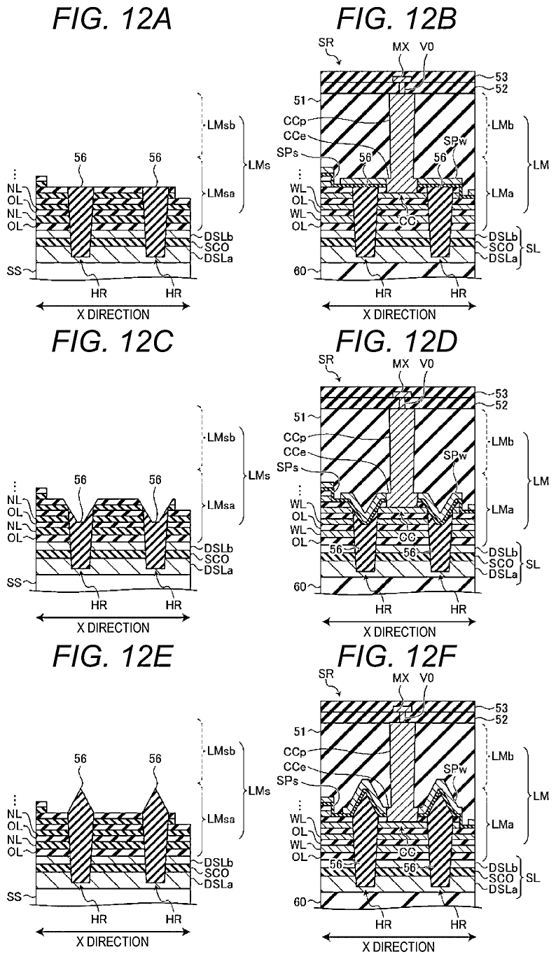

Here, the formation process of the contact CC described above will be described in more detail. FIGS. 12A to 14F are enlarged cross-sectional views along the X direction illustrating the details of the formation process of the contact CC of the semiconductor storage device 1 according to the embodiment.

As described above, when the region that is to be the staircase region SR later is formed into a staircase shape, the plurality of columnar portions HR that are previously formed are also processed together with the stacked bodies LMsa and LMsb. By such processing, the shape of the upper end portion of the columnar portion HR may vary. FIGS. 12A to 12F illustrate several examples of the shape that the columnar portion HR may have.

FIG. 12A illustrates an example when the processing rate of the columnar portion HR is substantially equal to, for example, the processing rate of the stacked bodies LMsa and LMsb. In such a case, the upper end portion of the columnar portion HR exposed on the terrace surface of each step of the staircase shape formed in the stacked bodies LMsa and LMsb has a substantially flat shape.

As illustrated in FIG. 12B, from the above state, the substantially flat stopper layers SPs and SPw are subsequently formed on the entire terrace surface having a substantially flat staircase shape including the upper surface of the columnar portion HR. In addition, in the example of FIG. 12B, the contact CC to be formed thereafter reaches, for example, the terrace surface between the plurality of columnar portions HR without being misaligned. In such a contact CC, the lower end portion CCe including the penetrated portion of the stopper layers SPs and SPw is enlarged in diameter in the direction along the XY plane along the surface of the stopper layers SPs and SPw and the like.

FIG. 12C illustrates an example when the processing rate of the columnar portion HR is higher than, for example, the processing rate of the stacked bodies LMsa and LMsb. In such a case, the upper end portion of the columnar portion HR has a shape in which the upper end portion is recessed in a mortar shape from the terrace surfaces of each step of the staircase shapes formed in the stacked bodies LMsa and LMsb. At this time, the terrace surface around the columnar portion HR may also have a shape that is recessed in a mortar shape toward the columnar portion HR.

As illustrated in FIG. 12D, the stopper layers SPs and SPw subsequently cover the terrace surfaces in a mortar shape along the terrace surfaces recessed in a mortar shape toward the columnar portion HR. However, when the contact CC formed thereafter is formed without being misaligned and without interfering with the columnar portion HR, the contact CC reaches a substantially flat portion of the terrace surface while avoiding a portion having a mortar shape. Therefore, the lower end portion CCe of the contact CC including the portion that penetrates the stopper layers SPs and SPwn is enlarged in diameter in the direction along the flat portion of the stopper layers SPs and SPw in the XY plane.

FIG. 12E shows an example when the processing rate of the columnar portion HR is lower than, for example, the processing rate of the stacked bodies LMsa and LMsb. In such a case, the upper end portion of the columnar portion HR has a conical shape that protrudes from the terrace surfaces of each step of the staircase shape formed in the stacked bodies LMsa and LMsb.

As illustrated in FIG. 12F, the stopper layers SPs and SPw subsequently cover the upper end portions of the columnar portions HR protruding from the terrace surface. However, when the contact CC formed thereafter is formed without being misaligned and without interfering with the columnar portion HR, the contact CC reaches a substantially flat portion of the terrace surface while avoiding portions in which the columnar portion HR and the stopper layers SPs and SPw protrude. Therefore, the lower end portion CCe of the contact CC including the portion that penetrates the stopper layers SPs and SPw and the like is enlarged in diameter in the direction along the flat portion of the stopper layers SPs and SPw and the like in the XY plane.

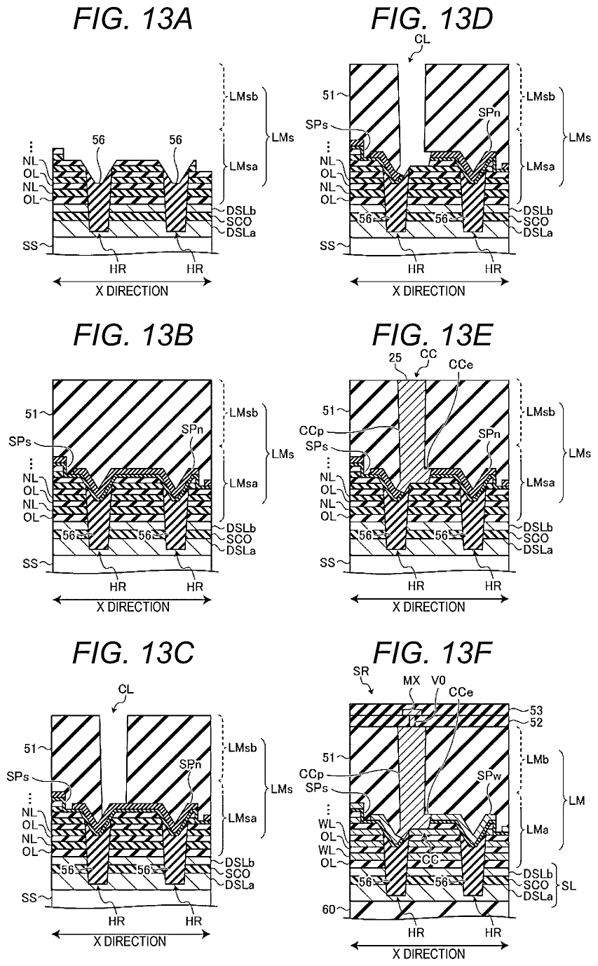

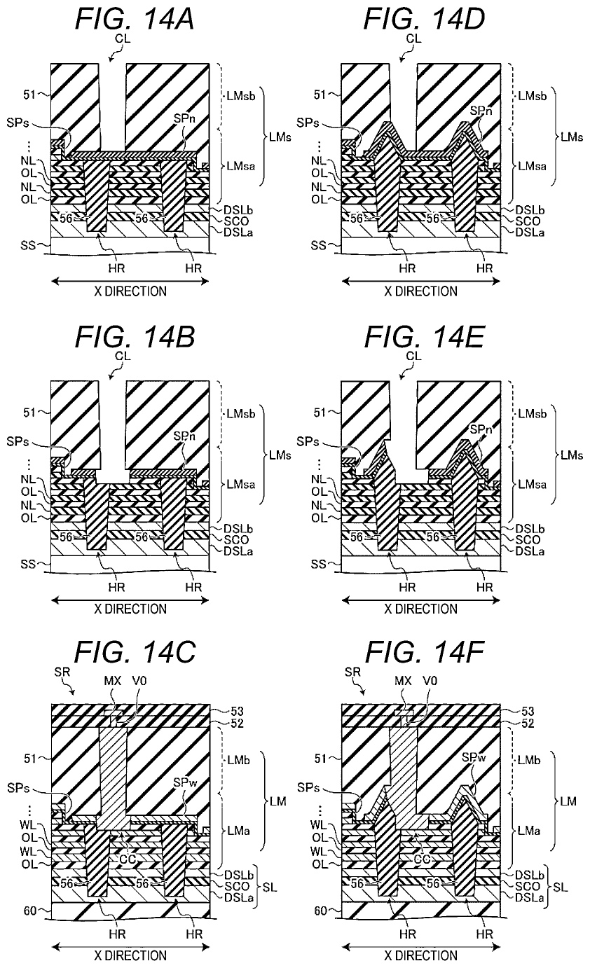

Next, an example when the contact CC is misaligned and is in contact with the columnar portion HR is illustrated in FIGS. 13A to 14F.

FIGS. 13A to 13F illustrate an example in which the columnar portion HR and the terrace surface around the columnar portion HR are recessed in a mortar shape toward the center of the columnar portion HR and the misalignment occurs in the contact CC.

FIG. 13A is an example of a staircase shape in which the terrace surface has a mortar shape as in FIG. 12C described above.

As illustrated in FIG. 13B, the stopper layers SPs and SPn are subsequently formed along the terrace surface having a mortar shape. In addition, the insulating layer 51 covering the staircase shape is formed via the stopper layers SPs and SPn.

As illustrated in FIG. 13C, the contact hole CL that penetrates the insulating layer 51 and reaches the stopper layer SPn that covers the terrace surface is formed. At this time, in the example of FIG. 13C, the contact hole CL is misaligned, and the lower end portion of the contact hole CL reaches a portion of the stopper layer SPn having a mortar shape.

As illustrated in FIG. 13D, the bottom surface of the contact hole CL is subjected to the wet etching process, and the contact hole CL reaching the insulating layer NL immediately below the terrace surface is formed. At this time, a lower end portion of the contact hole CL including the penetrated portion of the stopper layer SPn is enlarged in diameter along the surface of the stopper layer SPn. In the example of FIG. 13D, the lower end portion of the contact hole CL extends toward a columnar portion HR side along the surface of the mortar-shaped stopper layer SPn on one end side, and extends in the direction along the XY plane along the substantially flat surface of the stopper layer SPn on the other end side.

As illustrated in FIG. 13E, the contact hole CL having the lower end portion enlarged in diameter is filled with the conductive layer 25 to form the contact CC.

As illustrated in FIG. 13F, thereafter, the insulating layers NL of the stacked bodies LMsa and LMsb are replaced, and the stacked body LM having a plurality of word lines WL is formed. At this time, the stopper layer SPn is also replaced with the conductive material in the same manner, and the stopper layer SPw is formed.

Thereby, the contact CC is connected to the upper surface of the word line WL and the end surface of the word line WL exposed at the end portion of the mortar-shaped inclined surface with the lower end portion CCe. Further, by this, the stopper layer SPw is electrically connected to the word line WL that is to be connected to the contact CC through the lower end portion CCe of the contact CC. However, even in this case, as described above, since the stopper layer SPw is not in contact with the rest of word lines WL, there is no problem with the electrical characteristics.

FIGS. 14A to 14F illustrate examples when the entire terrace surface including the upper surface of the columnar portion HR has a substantially flat shape or the columnar portion HR has a shape protruding from the terrace surface into a conical shape and a misalignment occurs in the contact CC.

FIG. 14A is an example of a staircase shape in which the terrace surface is substantially flat, as in FIG. 12A described above. In this case, the stopper layers SPs and SPn subsequently follow a substantially flat terrace surface. In addition, the insulating layer 51 covering the staircase shape is formed via the stopper layers SPs and SPn.

In addition, the contact hole CL that penetrates the insulating layer 51 and reaches the stopper layer SPn that covers the terrace surface is formed. At this time, a misalignment of the contact hole CL occurs, and the lower end portion of the contact hole CL is formed at a position where a part of the lower end portion overlaps with one of the columnar portions HR in the stacking direction of the stacked bodies LMsa and LMsb.

As illustrated in FIG. 14B, the bottom surface of the contact hole CL is subjected to the wet etching process, and the contact hole CL that reaches the insulating layer NL immediately below the terrace surface is formed. At this time, the terrace surface including the upper end portion of the columnar portion HR is substantially flat. Therefore, a lower end portion of the contact hole CL including the penetrated portion of the stopper layer SPn is enlarged in diameter in a direction along the XY plane along the surface of the stopper layer SPn.

As illustrated in FIG. 14C, the contact hole CL having the lower end portion enlarged in diameter is filled with the conductive layer 25 to form the contact CC. In addition, thereafter, the insulating layers NL and the stopper layers SPn of the stacked bodies LMsa and LMsb are replaced, and the stacked body LM having the plurality of word lines WL and the stopper layer SPw are formed.

Thereby, the contact CC is connected to a part of the lower end portion CCe on the upper surface of the word line WL. In the example of FIG. 14C, one end portion of the lower end portion CCe of the contact CC extends on the upper end portion of the columnar portion HR, and is not conductive with the word line WL. However, the other end portion of the lower end portion CCe of the contact CC extends on the word line WL and may be conductive with the word line WL.

Further, by this, the stopper layer SPw is electrically connected to the word line WL to be connected to the contact CC through the lower end portion CCe of the contact CC.

FIG. 14D is an example in which the columnar portion HR protrudes from the terrace surface in a conical shape, as in FIG. 12E described above. In this case, the stopper layers SPs and SPn are subsequently formed on the terrace surface to also cover the protruding columnar portion HR. In addition, the insulating layer 51 covering the staircase shape is formed via the stopper layers SPs and SPn.

In addition, the contact hole CL that penetrates the insulating layer 51 and reaches the stopper layer SPn that covers the terrace surface is formed. At this time, a misalignment of the contact hole CL occurs, and the lower end portion of the contact hole CL is formed at a position where a part of the lower end portion overlaps with one of the columnar portions HR in the stacking direction of the stacked bodies LMsa and LMsb.

As illustrated in FIG. 14E, the bottom surface of the contact hole CL is subjected to the wet etching process, and the contact hole CL that reaches the insulating layer NL immediately below the terrace surface is formed. At this time, the upper end portion of the columnar portion HR protrudes from the terrace surface. Therefore, in the example of FIG. 14E, the lower end portion of the contact hole CL extends along the upper end portion of the protruding columnar portion HR on one end side, and extends in the direction along the XY plane along the surface of the substantially flat stopper layer SPn on the other end side.

As illustrated in FIG. 14F, the contact hole CL having the lower end portion enlarged in diameter is filled with the conductive layer 25 to form the contact CC. In addition, thereafter, the insulating layers NL and the stopper layers SPn of the stacked bodies LMsa and LMsb are replaced, and the stacked body LM having the plurality of word lines WL and the stopper layer SPw are formed.

Thereby, the contact CC is exclusively connected to the upper surface of the word line WL at a part of the lower end portion CCe. In the example of FIG. 14F, one end portion of the lower end portion CCe of the contact CC extends while covering the protruding portion of the columnar portion HR, and is not conductive with the word line WL. However, the other end portion of the lower end portion CCe of the contact CC extends on the word line WL and may be conductive with the word line WL.

Further, by this, the stopper layer SPw is electrically connected to the word line WL to be connected to the contact CC through the lower end portion CCe of the contact CC.

As described above, according to the semiconductor storage device 1 of the embodiment, the contact CC is more reliably connected to the word line WL to be connected, regardless of the shape of the columnar portion HR processed in parallel when the staircase shape is formed, and regardless of whether the misalignment occurs in the contact CC.

### Comparative Example

The semiconductor storage device such as a three-dimensional non-volatile memory is manufactured through a process of forming a stacked body in which a plurality of word lines are stacked by replacing, for example, a stacked body in which a sacrificial layer is stacked in multiple layers. Thereafter, a process of forming a contact in a terrace portion through which an electrically connected to a plurality of word lines is provided, is performed.

At the time of forming the contact, for example, a plurality of contact holes having different reach depths are collectively formed by penetrating an insulating layer covering the staircase portion. At this time, in order to prevent a part of the contact hole having a different depth from penetrating the word line to be connected, a stopper layer covering the staircase portion may be previously formed.

In addition, a plurality of columnar portions may be formed in the staircase portion of the semiconductor storage device in order to support the structure of the stacked body when the stacked body is replaced. Even when the contact is misaligned with the disposition position of the columnar portion at the time of forming the contact, providing the above-described stopper layer prevents the contact from being formed through the columnar portions.

Such a stopper layer is formed of, for example, the same material as the sacrificial layer. Therefore, when the word line is formed from the sacrificial layer, the stopper layer at the position where the slit is formed is previously removed such that the stopper layer is not replaced together. However, in recent years, the number of layers of the word line tends to increase, and the difference in height position between the upper layer and the lower layer of the staircase portion is also increasing. Therefore, it is also extremely difficult to form an opening by exposing a mask pattern used to remove the stopper layer.

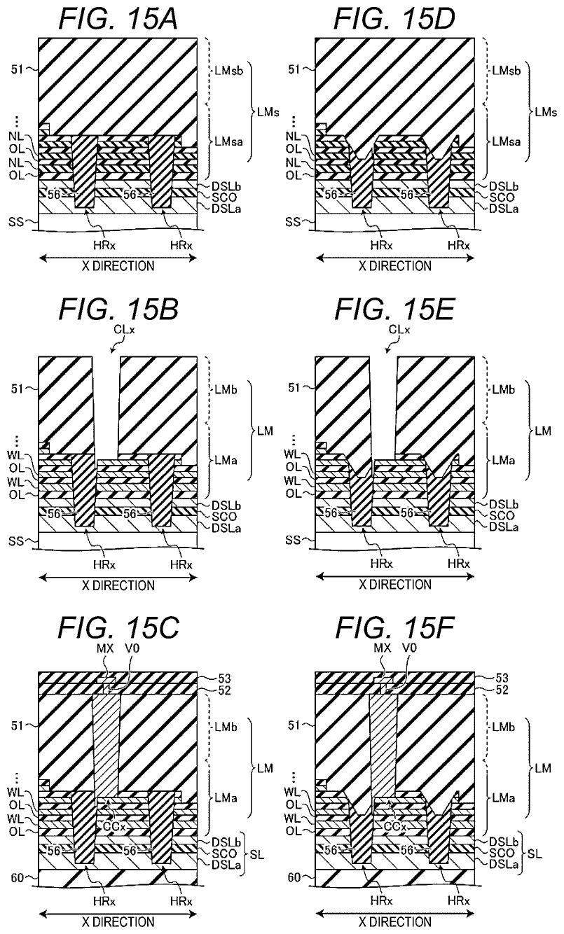

In addition, when the staircase portion is formed after the formation of the columnar portion, the terrace surface may be processed in a mortar shape toward the columnar portion due to a difference in the processing rate between the sacrificial layer or the like that makes up the stacked body and the insulating layer or the like that makes up the columnar portion. When the exposure difficulty of the mask pattern increases and the stopper layer cannot be used, the risk of poor formation of the contact due to the penetration of the word line to be connected is further increased. FIGS. 15A to 15F illustrate the state.

FIGS. 15A to 15F are enlarged cross-sectional views taken along the X direction, illustrating the formation process of a contact CCx of the semiconductor storage device according to the comparative example.

More specifically, FIGS. 15A to 15F illustrate an example in which the entire terrace surface including the upper surface of a columnar portion HRx has a substantially flat shape or the terrace surface has a mortar shape toward the columnar portion HRx and a misalignment occurs in the contact CCx. As illustrated in FIGS. 15A to 15F, in the comparative example, the insulating layer 51 directly covers the staircase shape.

FIG. 15A is an example of a staircase shape in which a terrace surface is substantially flat.

As illustrated in FIG. 15B, the plurality of word lines WL are formed from the plurality of insulating layers NL by the replacement process, and then a contact hole CLx penetrating the insulating layer OL that makes up the insulating layer 51 and the terrace surface, and reaching the insulating layer NL immediately below the insulating layer OL is formed.

At this time, a misalignment of the contact hole CLx occurs, and the lower end portion of the contact hole CLx is formed at a position where a part of the lower end portion overlaps with one of the columnar portions HRx in the stacking direction of the stacked bodies LMsa and LMsb. Thereby, a part of the lower end portion of the contact hole CLx may reach a layer lower than the insulating layer NL, which is the target to be reached, via the columnar portion HRx.

As illustrated in FIG. 15C, the contact hole CLx, which partially reaches the lower layer, is filled with the conductive layer, and the contact CCx is formed. In the example of FIG. 15C, the lower end portion of the contact CCx is stopped in the insulating layer OL immediately below the word line WL to be connected, and is not connected to the word line WL on a further lower layer.

Therefore, a short circuit does not occur between the word line WL to be connected to the contact CCx and the word line WL on the lower layer. However, since the lower end portion of the contact CCx extends to immediately above the word line WL at the lower layer, there is a possibility that the breakdown voltage between the word lines WL is insufficient. In addition, when the lower end portion of the contact CCx further extends downward, a short circuit may occur between the word lines WL.

FIG. 15D is an example of a staircase shape in which the terrace surface is in a mortar shape toward the columnar portion HR. In this case, the reach depth of the lower end portion of the contact hole CLx is increased, and the risk of a short circuit between the word lines WL is further increased.

As illustrated in FIG. 15E, a part of the lower end portion of the contact hole CLx, which penetrates through the insulating layers 51 and OL and reaches the underlying insulating layer NL, extends further into the lower layer via the columnar portion HRx, reaching the lower word line WL below the word line WL to be connected.

As illustrated in FIG. 15F, the contact hole CLx, which partially reaches the lower layer, is filled with the conductive layer and the contact CCx is formed. In the example of FIG. 15F, the lower end portion of the contact CCx is connected to both the word line WL to be connected and the word line WL on the lower layer thereof, and a short circuit occurs between these word lines WL.

As described above, in a process of manufacturing the semiconductor storage device, a misalignment may occur when the contact hole is formed. When the misaligned contact hole interferes with the columnar portion, the contact hole may reach a position deeper than the word line to be connected, and an insufficient breakdown voltage or a short circuit between the word lines may occur.

Such a defect becomes more significant when a terrace surface around a columnar portion is formed in a shape recessed in a mortar shape when forming a staircase shape.

According to the semiconductor storage device 1 of the embodiment, the contact CC reaches the word line WL to be connected by penetrating the stopper layer SPw disposed above the word line WL to be connected to the contact CC among the plurality of word lines WL.

As described above, the stopper layer SPw is obtained by replacing the stopper layer SPn used when forming the contact hole CL. As described above, by forming the contact hole CL using the stopper layer SPn, it is possible to prevent the insufficient breakdown voltage and a short circuit between the word lines WL from occurring even when the contact hole CL is misaligned.

According to the semiconductor storage device 1 of the embodiment, the contact CC extends along the surface of the mortar-shaped stopper layer SPw on the lower end portion CCe including the penetrated portion of the stopper layer SPw, and is connected to the word line WL to be connected at least in a part of the lower end portion CCe.

As described above, when the terrace surface is processed into a mortar shape toward the columnar portion HR when forming the staircase shape, the risk of a short circuit defect between the word lines WL and the like increases. However, even in this case, the lower end portion CCe of the contact CC extends along the surface of the mortar-shaped stopper layer SPw, so that the insufficient breakdown voltage, a short circuit, and the like between the word lines WL can be prevented.

With the semiconductor storage device 1 according to the embodiment, the lower end portion of the contact CC is in contact with the upper end portion of the columnar portion HR. In this way, even when the contact CC and the columnar portion HR interfere with each other, it is possible to prevent the insufficient breakdown voltage and the short circuit between the word lines WL.

According to the semiconductor storage device 1 of the embodiment, the stopper layer SPw is not connected to any of the plurality of word lines WL other than the word line WL to be connected to the contact CC. As a result, when the stacked bodies LMsa and LMsb are replaced, the stopper layer SPn may also be replaced. Therefore, there is no need to previously remove the stopper layer SPn at the slit ST formation position, and the introduction of the stopper layer SPn into the staircase portion SCP is facilitated.

According to the method for manufacturing the semiconductor storage device 1 of the embodiment, after at least the contact hole CL is formed, the plurality of insulating layers NL are replaced with the plurality of word lines WL to form the stacked body LM in which the plurality of word lines WL and the plurality of insulating layers OL are alternately stacked in one layer by one layer.

As described above, by forming the contact hole CL before the insulating layer NL and the stopper layer SPn are replaced with the word line WL and the stopper layer SPw, respectively, it is not necessary to penetrate the stopper layer SPw to form the contact hole CL, and the formation of the contact CC is facilitated.

With the semiconductor storage device 1 according to the embodiment, the stopper layer SPw is disposed above the word line WL to be connected to the contact CC via the stopper layer SPs. In this way, by interposing the stopper layer SPs, for example, when the stopper layer SPn before replacement is processed in various ways, the stacked body LM can be protected.

According to the semiconductor storage device 1 of the embodiment, the stopper layer SPs is also disposed on the step surfaces of the plurality of word lines WL processed into a staircase shape. As a result, the word line WL in the upper layer of the word line WL to be connected to the contact CC is prevented from being connected to the stopper layer SPw at the end surface of the step surface.

In the above-described embodiment, the staircase region SR including the staircase portion SCP is disposed at both end portions of the stacked body LM in the X direction. However, for example, a staircase region including a staircase portion formed by digging a central portion of the stacked body in a mortar shape may be disposed in the stacked body.

In addition, in the above-described embodiment, the peripheral circuit CBA that contributes to the operation of the memory cell MC is disposed above the semiconductor substrate SB which is stacked on the stacked body LM. However, the stacked body may be stacked on the peripheral circuit, which is disposed above the semiconductor substrate and includes the transistor. Alternatively, the stacked body may be disposed on the same semiconductor substrate as the peripheral circuit.

In addition, in the above-described embodiment, the semiconductor storage device 1 includes the stacked body LM of 2 tiers including stacked bodies LMa and LMb. However, the semiconductor storage device may include a stacked body of 1 tier or 3 tiers or more. In a multi-tier type semiconductor storage device, the number of layers of the word line WL may be further increased easily.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall in the scope and spirit of the disclosure.

What is claimed is:

1. A semiconductor storage device comprising:
a stacked body having a plurality of conductive layers and a plurality of first insulating layers that are alternately stacked, and a staircase portion in which the plurality of conductive layers have been processed into a staircase shape;
a contact disposed in the staircase portion and connected to a first conductive layer, which is one of the plurality of conductive layers; and
a first pillar that extends in a stacking direction of the stacked body in a portion of the stacked body different from the staircase portion and forms memory cells at each intersection of the first pillar and at least a part of the plurality of conductive layers,
wherein the contact penetrates a second conductive layer, which is not one of the plurality of conductive layers and disposed above the first conductive layer, and reaches the first conductive layer to be in contact therewith.

2. The semiconductor storage device according to claim 1,
wherein the second conductive layer contains the same material as the plurality of conductive layers.

3. The semiconductor storage device according to claim 1, further comprising:
a second pillar that extends in the stacking direction in the staircase portion,
wherein the second conductive layer is recessed in a mortar shape from a periphery of the second pillar toward a center of the second pillar.

4. The semiconductor storage device according to claim 3,
wherein the contact extends along a surface of the second conductive layer having the mortar shape at a lower end portion thereof, and is connected to the first conductive layer in at least a part of the lower end portion thereof.

5. The semiconductor storage device according to claim 3,
wherein a lower end portion of the contact is in contact with an upper end portion of the second pillar.

6. The semiconductor storage device according to claim 1, further comprising:
a second insulating layer in contact with the second conductive layer and the first conductive layer.

7. The semiconductor storage device according to claim 6,
wherein the second insulating layer is also disposed on step surfaces of the plurality of first conductive layers processed into a staircase shape.

8. The semiconductor storage device according to claim 1, wherein a lower end portion of the contact has a cross-sectional area in a plane orthogonal to the stacking direction that is larger than that of an upper end portion of the contact.

9. A method for manufacturing a semiconductor storage device, the method comprising:
forming a first stacked body in which a plurality of first insulating layers and a plurality of second insulating layers are alternately stacked;
forming a first pillar that has a semiconductor layer extending in a stacking direction of the first stacked body in a first region of the first stacked body;
forming a second pillar extending in the stacking direction in a second region of the first stacked body;
forming a staircase portion by processing the plurality of first insulating layers into a staircase shape in the second region of the first stacked body;
forming a third insulating layer made of the same material as the plurality of first insulating layers, that covers the staircase portion along a staircase shape of the staircase portion; and
forming a contact hole at a position overlapping with a terrace surface of the staircase portion in the stacking direction while using the third insulating layer as a stopper layer.

10. The method for manufacturing a semiconductor storage device according to claim 9, further comprising:
extending the contact hole through the third insulating layer to one of the first insulating layers below the terrace surface overlapping with the contact hole in the stacking direction.

11. The method for manufacturing a semiconductor storage device according to claim 10, further comprising:
forming a contact by filling the contact hole with a metal layer; and
forming a second stacked body in which a plurality of conductive layers and the plurality of second insulating layers are alternately stacked by replacing the plurality of first insulating layers with the plurality of conductive layers.

12. The method for manufacturing a semiconductor storage device according to claim 11, wherein forming the second stacked body includes:
forming a slit extending in the stacking direction and a first direction intersecting with the stacking direction, in the first stacked body to divide the first stacked body; and
replacing the third insulating layer with a conductive layer via the slit while the plurality of first insulating layers are replaced with the plurality of conductive layers via the slit.

13. The method for manufacturing a semiconductor storage device according to claim 11,
wherein, when forming the third insulating layer, the third insulating layer that covers a step surface of the staircase portion is removed while the third insulating layer that covers the terrace surface of the staircase portion is retained.

14. The method for manufacturing a semiconductor storage device according to claim 11, wherein a lower end portion of the contact has a cross-sectional area in a plane orthogonal to the stacking direction that is larger than that of an upper end portion of the contact.

15. A semiconductor storage device comprising:
a stacked body having a plurality of first conductive layers and a plurality of first insulating layers that are alternately stacked in a first direction, and a staircase portion in which the plurality of first conductive layers have been processed into a staircase shape, wherein the staircase portion has terrace surfaces at different heights that face the first direction and step surfaces connecting the terrace surfaces that face a second direction that crosses the first direction;
a second insulating layer on the terrace surfaces and step surfaces of the staircase portion; and
a plurality of second conductive layers that are respectively on portions of the second insulating layer that are on the terrace surfaces;
a plurality of contacts extending in the first direction in the staircase portion, wherein each of the contacts penetrates one of the plurality of second conductive layers and the second insulating layer to be in contact with one of the plurality of first conductive layers; and
a plurality of first pillars extending in the first direction in a portion of the stacked body different from the staircase portion and forms memory cells at each intersection of the first pillars and at least a part of the plurality of conductive layers.

16. The semiconductor storage device according to claim 15,
wherein the second conductive layers contains the same material as the first conductive layers.

17. The semiconductor storage device according to claim 15, wherein a density of the second pillars arranged in the staircase portion is less than a density of the first pillars arranged in the portion of the stacked body different from the staircase portion.

18. The semiconductor storage device according to claim 15, wherein a lower end portion of one of the contacts is in contact with an upper end portion of one of the second pillars.

19. The semiconductor storage device according to claim 15, wherein a lower end portion of each of the contacts has a cross-sectional area in a plane orthogonal to the first direction that is larger than that of an upper end portion thereof.

20. The semiconductor storage device according to claim 15, wherein a bottom surface of each of the contacts is in contact with a top surface of one of the plurality of first conductive layers.
